(19) United States
(12) Patent Application Publication
(10) Pub. No.: US 2023/0137579 A1
(43) Pub. Date: May 4, 2023

(54) SELF-LUMINOUS DISPLAY DEVICE

(71) Applicants: WUHAN CHINA STAR OPTOELECTRONICS TECHNOLOGY CO., LTD., Wuhan (CN); WUHAN CHINA STAR OPTOELECTRONICS SEMICONDUCTOR DISPLAY TECHNOLOGY CO., LTD., Wuhan (CN)

(72) Inventor: Kailong WU, Wuhan (CN)

(21) Appl. No.: 17/419,607

(22) PCT Filed: Jun. 3, 2021
(86) PCT No.: PCT/CN2021/098063

§ 371 Date: Jun. 29, 2021

(30) Foreign Application Priority Data
May 25, 2021 (CN) 202110568822.X

(51) Int. Cl. G09G 3/3233; H10K 59/80

(52) U.S. Cl. CPC G09G 3/3233; H10K 59/8794; G09G 2320/041; G09G 2300/0452; G09G 2320/0233; H10K 59/35

(57) ABSTRACT

The present invention provides a self-luminous display device, including a self-luminous display panel and a temperature detection film layer. The self-luminous display panel is provided with a driving unit and multiple pixel units. The pixel units are all electrically connected to the driving unit. The temperature detection film layer is attached to one side of the self-luminous display panel for real-time detection of temperature values of the self-luminous display panel.

### FIELD OF DISCLOSURE

The present application relates to a field of display technology and in particular, to a self-luminous display device.

### DESCRIPTION OF RELATED ART

With development of flat display technology, customers demand for display panels with higher display performance. In recent years, self-luminous displays such as mini-LED displays, micro-LED displays, and OLED displays have been developed. Among them, the OLED displays are developing rapidly in the world, and OLED display technology is also improving day by day. However, there are still some process or technical shortcomings and flaws that need to be amended and improved to show customers more colorful and dreamy realistic effects.

Taking the OLED displays as an example, different from other display technologies, OLED display technology uses self-luminous characteristics of an array of luminescent materials under electrical excitation to achieve screen display functions. Optical, electrical, and thermodynamic properties of the luminescent materials and other auxiliary organic functional materials have a greater impact on luminous characteristics of an array of light-emitting elements of the OLED display, and play a decisive role in display performance of the OLED displays, causing luminous brightness to vary with temperatures. Therefore, how to maintain stable environmental conditions of the light-emitting elements is an important key to ensure good display performance of the OLED displays. In addition, how to use external technical means to compensate and eliminate a difference in the display performance caused by changes in environmental factors is also a good idea to ensure that the OLED displays have good display performance. Other self-luminous displays also have similar problems.

In view of the above shortcomings and defects of conventional techniques, the present invention provides a self-luminous display device to solve a technical problem that luminous brightness of the conventional self-luminous display device changes with temperatures.

### SUMMARY

The present invention is directed to providing a self-luminous display device, comprising: a self-luminous display panel provided with a driving unit and a plurality of pixel units, wherein the pixel units are all electrically connected to the driving unit; and a temperature detection film layer attached to one side of the self-luminous display panel for real-time detection of a plurality of temperature values of the self-luminous display panel; wherein the temperature detection film layer is provided with a sensing control unit and a plurality of temperature sensors arranged in an array, all the temperature sensors are electrically connected to the sensing control unit, the sensing control unit is electrically connected the driving unit of the self-luminous display panel, and the driving unit is configured to adjust a driving voltage of each of the pixel units in real time according to the temperature values of the self-luminous display panel.

In the self-luminous display device according to one embodiment of the present application, the sensing control unit is an integrated circuit chip, the integrated circuit chip is disposed in the temperature detection film layer, and the temperature sensors are arranged around the integrated circuit chip.

In the self-luminous display device according to one embodiment of the present application, the pixel units comprise a plurality of red sub-pixels, a plurality of green sub-pixels, and a plurality of blue sub-pixels; and each of the red sub-pixels is arranged corresponding to one of the temperature sensors, each of the green sub-pixels is arranged corresponding to one of the temperature sensors, and each of the blue sub-pixels is arranged corresponding to one of the temperature sensors.

In the self-luminous display device according to one embodiment of the present application, each of the pixel units is arranged corresponding to one of the temperature sensors.

In the self-luminous display device according to one embodiment of the present application, multiple ones of the pixel units are arranged corresponding to one of the temperature sensors.

In the self-luminous display device according to one embodiment of the present application, the self-luminous display device further comprises a flexible backplate attached to a lower surface of the self-luminous display panel, wherein the temperature detection film layer is disposed between the self-luminous display panel and the flexible backplate, or the temperature detection film layer is disposed under the flexible backplate.

In the self-luminous display device according to one embodiment of the present application, the self-luminous display device further comprises a foam layer attached to a lower surface of the flexible backplate, wherein the temperature detection film layer is disposed between the flexible backplate and the foam layer, or the temperature detection film layer is disposed under the foam layer.

In the self-luminous display device according to one embodiment of the present application, the self-luminous display device further comprises a heat dissipation functional layer attached to a lower surface of the foam layer, wherein the temperature detection film layer is disposed between the foam layer and the heat dissipation functional layer, or the temperature detection film layer is disposed in the heat dissipation functional layer, or the temperature detection film layer is disposed under the heat dissipation functional layer.

In the self-luminous display device according to one embodiment of the present application, the heat dissipation functional layer comprises a base layer, a graphite layer, and a copper foil layer; the base layer is attached to the lower surface of the foam layer; the graphite layer is disposed on a lower surface of the base layer; and the copper foil layer is attached to a lower surface of the graphite layer, wherein when the temperature detection film layer is disposed in the heat dissipation functional layer, the temperature detection film layer is disposed between the graphite layer and the copper foil layer; and when the temperature detection film layer is disposed on a lower surface of the heat dissipation functional layer, the temperature detection film layer is disposed on a lower surface of the copper foil layer.

In the self-luminous display device according to one embodiment of the present application, the sensing control unit is configured to store information related to temperatures/grayscale voltages/data compensation voltages to provide the driving unit with the data compensation voltage required by each of the pixel units according to a position of the corresponding temperature sensor.

Advantages of the present application:

Advantages of the present invention are as follows. The present application provides a display device. The present application provides a temperature detection film layer which comprises a sensing control unit and temperature sensors and is arranged at one side of a self-luminous display panel. Accordingly, temperatures of the self-luminous display panel are detected by the temperature sensors and fed back to the sensing control unit. The sensing control unit provides a driving unit with a data compensation voltage required by each pixel unit according to a position of the corresponding temperature sensor, so that the driving unit can adjust a driving voltage of each pixel unit in real time to reinforce brightness of a darker area and lower brightness of a brighter area, thereby improving overall display uniformity.

### BRIEF DESCRIPTION OF DRAWINGS

FIG. 1 is a schematic structural plan view illustrating a self-luminous display panel according to a first embodiment of the present invention.

FIG. 2 is a schematic structural plan view illustrating a temperature detection film layer according to the first embodiment of the present invention.

FIG. 3 is a schematic structural cross-sectional view illustrating a self-luminous display device according to the first embodiment of the present invention.

FIG. 4 is a graph of a current efficiency ratio varying with a temperature of a red organic light emitting diode (OLED) component corresponding to a red sub-pixel according to the first embodiment of the present invention.

FIG. 5 is a graph of a current efficiency ratio varying with a temperature of a green OLED component corresponding to a green sub-pixel according to the first embodiment of the present invention.

FIG. 6 is a graph of a current efficiency ratio varying with a temperature of a blue OLED component corresponding to a blue sub-pixel according to the first embodiment of the present invention.

FIG. 7 is a schematic structural cross-sectional view illustrating the self-luminous display device according to a second embodiment of the present invention.

FIG. 8 is a schematic structural cross-sectional view illustrating the self-luminous display device according to a third embodiment of the present invention.

FIG. 9 is a schematic structural cross-sectional view illustrating the self-luminous display device according to a fourth embodiment of the present invention.

FIG. 10 is a schematic structural cross-sectional view illustrating the self-luminous display device according to a fifth embodiment of the present invention.

FIG. 11 is a process flow diagram illustrating a driving method of a display device according to one embodiment of the present invention.

The labels in the drawings are as follows:
cover plate 1, optical adhesive 2, polarizer 3, light-emitting layer 4, substrate layer 5, backplate 6, foam layer 7, heat dissipation functional layer 8, self-luminous display panel 10, driving unit 11, pixel unit 12, temperature detection film layer 20, sensing control unit 21, temperature sensor 22, base layer 81, graphite layer 82, copper foil layer 83, self-luminous display device 100.

### DETAILED DESCRIPTION OF EMBODIMENTS

The technical solutions of the present application will be clearly and completely described below in conjunction with the accompanying drawings with reference to the embodiments of the present application. Obviously, the described embodiments are only some of the embodiments of the present application, rather than all the embodiments. Based on the embodiments in the present application, all other embodiments obtained by those skilled in the art without creative work shall fall within the protection scope of the present application.

### First Embodiment

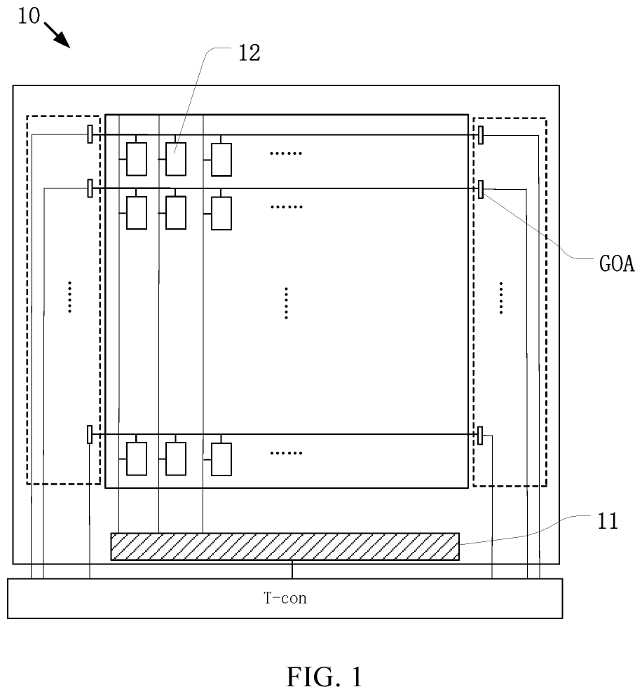

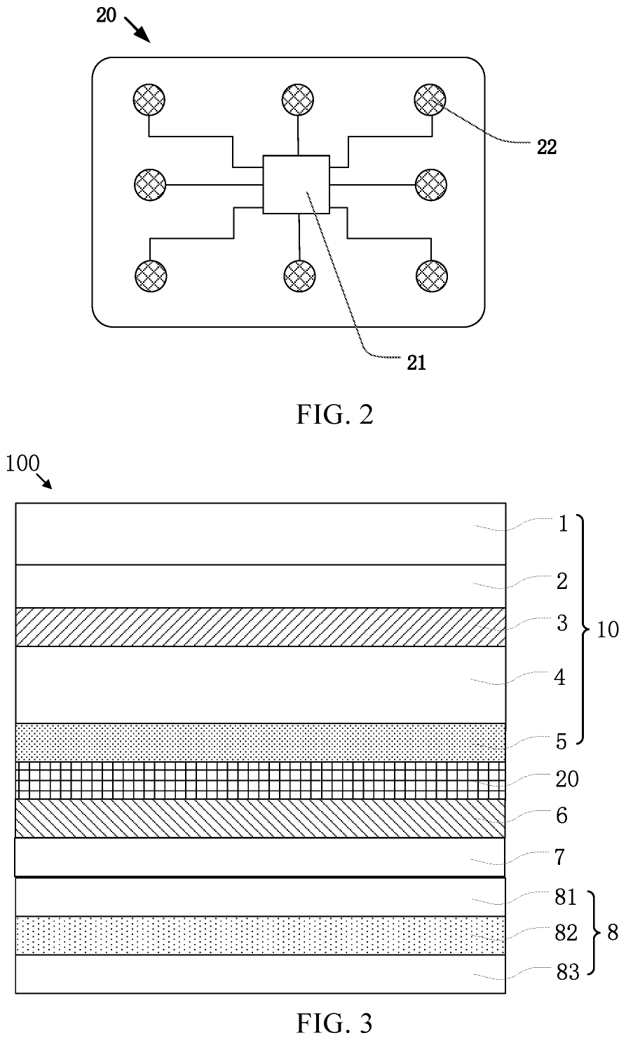

As shown in FIG. 1, FIG. 2, and FIG. 3, a self-luminous display device 100 is provided according to a first embodiment of the present application. The self-luminous display device 100 comprises a self-luminous display panel 10 and a temperature detection film layer 20. As shown in FIG. 1, the self-luminous display panel 10 is provided with a driving unit 11 and a plurality of pixel units 12, and the plurality of pixel units 12 are all electrically connected to the driving unit 11. As shown in FIG. 3, the temperature detection film layer 20 is attached to one side of the self-luminous display panel 10 for real-time detection of a plurality of temperature values of the self-luminous display panel 10. As shown in FIG. 2, the temperature detection film layer 20 is provided with a sensing control unit 21 and a plurality of temperature sensors 22 arranged in an array. The temperature sensors 22 are all electrically connected to the sensing control unit 21. The sensing control unit 21 is electrically connected to the driving unit 11 of the self-luminous display panel 10, and the driving unit 11 is configured to adjust a driving voltage of each of the pixel units 12 in real time according to the temperature values of the self-luminous display panel 10.

Specifically, the driving unit 11 is, for example, an individual integrated circuit chip or integrated with a source driver or a time control unit T-con. FIG. 1 shows that the driving unit 11 is integrated with the source driver. In addition, the self-luminous display panel 10 also comprises components such as a gate on array (GOA) unit, and a detailed description is omitted here for brevity.

In one embodiment of the present application, the sensing control unit 21 is an integrated circuit chip, the integrated circuit chip is arranged in the temperature detection film layer 20, and the temperature sensors 22 are arranged around the integrated circuit chip. The sensing control unit 21 is configured for storing information related to temperatures/grayscale voltages/data compensation voltages to provide the driving unit 11 with the data compensation voltage required by each of the pixel units 12 according to a position of the corresponding temperature sensor 22.

Specifically, the temperature sensors 22 are, for example, temperature sensitive resistors. An arrangement of the temperature sensors 22 and a position of the sensing control unit 21 in FIG. 2 are only examples, and the present application is not limited in this regard. In one embodiment of the present application, the temperature sensors 22 are arranged in the array, and the sensing control unit 21 is arranged at an edge of the array of the temperature sensors.

In one embodiment of the present application, the pixel units 12 comprise a plurality of red sub-pixels, a plurality of green sub-pixels, and a plurality of blue sub-pixels (hereinafter briefly referred to as RGB). Each of the red sub-pixels is arranged corresponding to one of the temperature sensors 22, each of the green sub-pixels is arranged corresponding to one of the temperature sensors 22, and each of the blue sub-pixels is arranged corresponding to one of the temperature sensors 22.

Specifically, the red sub-pixels, the green sub-pixels, and the blue sub-pixels are, for example, self-luminous components such as organic light emitting diode (OLED) components, mini-LED components, or micro-LED components, and the present application is not limited in this regard.

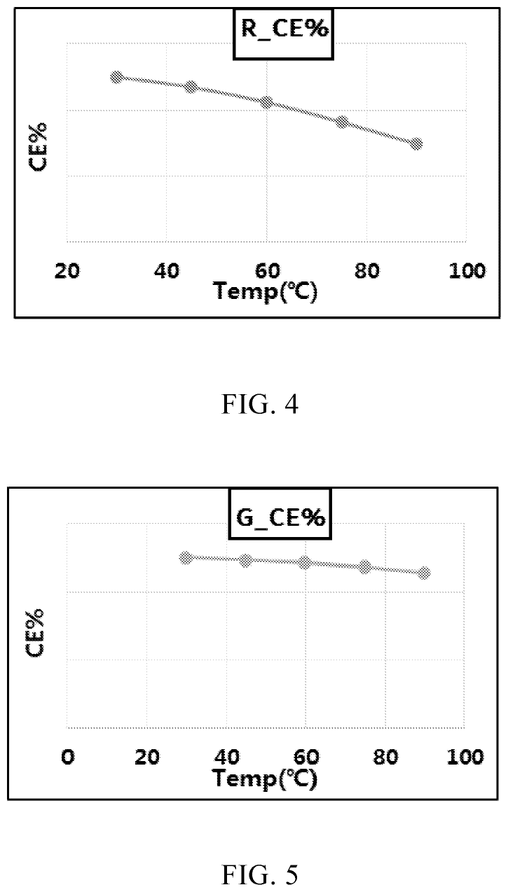

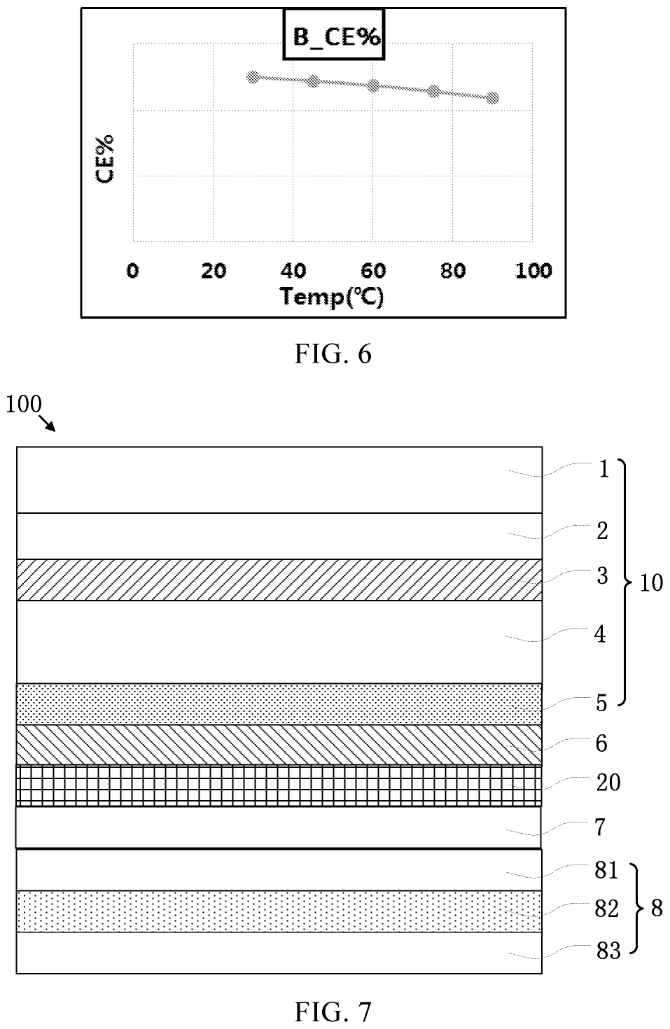

Please refer to FIG. 4, FIG. 5, and FIG. 6. FIG. 4 is a graph of a current efficiency ratio, varying with a temperature, of a red OLED component corresponding to the red sub-pixel. FIG. 5 is a graph of a current efficiency ratio, varying with a temperature, of a green OLED component corresponding to the green sub-pixel. FIG. 6 is a graph of a current efficiency ratio, varying with a temperature, of a blue OLED component corresponding to the blue sub-pixel. In FIGS. 4, 5, and 6, a horizontal axis labeled “Temp” represents a detected temperature, and a vertical axis labeled “CE %” is a current efficiency ratio, wherein CE is an abbreviation of current efficiency, and the current efficiency is a measurement parameter of luminous efficiency of the self-luminous display device 100, which has a positive correlation with luminous brightness and can indirectly indicate the luminous brightness. In OLED displays, depending on organic materials used, changes in ambient temperatures have different effects on RGB light-emitting components. Such characteristics of the light-emitting components of the OLED display lead to a certain degree of change in display performance of the OLED display when the ambient temperatures change greatly or temperatures of the OLED display change greatly from a large amount of heat generation. Specifically, brightness, color, color perception, and viewing angles are all affected. Therefore, the present application specifically sets the temperature sensors 22 at the positions of the sub-pixels of different colors to recognize brightness corresponding to different temperatures, so as to change the driving voltages of the sub-pixels to improve uniformity of the brightness.

In one embodiment of the present application, each of the pixel units 12 is arranged corresponding to one of the temperature sensors 22.

In one embodiment of the present application, multiple ones of the pixel units 12 are arranged corresponding to one of the temperature sensors 22. Preferably, multiple sub-pixels of a same color are arranged corresponding to one of the temperature sensors 22, so that one of the temperature sensors 22 can simultaneously recognize temperatures of the sub-pixels of the corresponding color to adjust the driving voltage of the pixel unit 12 in real time.

An example of a correlation between the temperatures and the driving voltages (Data) is as follows. At a room temperature T0, the RGB have brightness of L_{R0}, L_{G0}, L_{B0}, respectively, and their driving voltages correspond to V_{R0}, V_{G0}, V_{B0}, respectively. At a high temperature T1 (greater than the room temperature T0), the RGB has brightness of L_{R1}, L_{G1}, L_{B1}, respectively, and if their driving voltages are still corresponding to V_{R0}, V_{G0}, V_{B0}, then L_{R1}<L_{R0}, L_{G1}<L_{G0}, L_{B1}<L_{B0}, so the driving voltages need to be increased.

Through tests, it can be known that there is a stable correlation between the brightness and the temperatures of the device at a fixed temperature. If the brightness of the RGB can be restored to L_{R0}, L_{G0}, L_{B0} at T0 when the driving voltages are increased to V_{R1}, V_{G1}, V_{B1}, then the corresponding relationship information (T1, V_{R1}, V_{G1}, V_{B1}) is recorded. Similarly, relationships (T2, V_{R2}, V_{G2}, V_{B2}), (T3, V_{R3}, V_{G3}, V_{B3}), (T4, V_{R4}, V_{G4}, V_{B4}) between the driving voltages and the temperatures such as T2, T3, T4, etc. can also be established. Therefore, the corresponding relationships between the temperatures of the RGB and the driving voltages are established, and recorded in the sensing control unit 21 (the IC chip), and written into a switching program to work in cooperation with the temperature sensors. A purpose of the above operations is to write the relationships between the temperatures and the driving voltages in the sensing control unit 21. When the display panel is in operation, the driving voltages are adjusted according to temperature feedbacks from the sensors to achieve a purpose of stabilizing the brightness of the display panel, thus improving display quality.

As shown in FIG. 3, the display panel comprises a cover plate 1, an optical adhesive 2, a polarizer 3, a light-emitting layer 4, and a substrate layer 5 stacked in sequence from top to bottom. The light-emitting layer 4 comprises the pixel units 12. Preferably, the temperature detection film layer 20 is attached to a lower side of the substrate layer 5 of the self-luminous display panel 10. In this case, sensor elements of the temperature detection film layer 20 are closest to the self-luminous display panel 10, timeliness and effectiveness of temperature detection of the sensor elements are improved, and an adjustment effect is better.

In one embodiment of the present application, the self-luminous display device 100 further comprises a backplate 6 attached to a lower surface of the self-luminous display panel 10. The temperature detection film layer 20 is disposed between the self-luminous display panel 10 and the backplate 6.

In one embodiment of the present application, the self-luminous display device 100 further comprises a foam layer 7 attached to a lower surface of the backplate 6. The foam layer 7 serves as a buffer to protect the light-emitting layer 4.

In one embodiment of the present application, the self-luminous display device 100 further comprises a heat dissipation functional layer 8 attached to a lower surface of the foam layer 7 to achieve effective heat dissipation. Specifically, the heat dissipation functional layer 8 comprises a base layer 81, a graphite layer 82, and a copper foil layer 83. The base layer 81 is attached to the lower surface of the foam layer 7. The graphite layer 82 is disposed on a lower surface of the base layer 81, and the copper foil layer 83 is attached to a lower surface of the graphite layer 82.

### Second Embodiment

As shown in FIG. 7, the self-luminous display device 100 in the second embodiment 2 comprises most technical features of the first embodiment. The second embodiment is different from the first embodiment in that, the temperature detection film layer 20 of the second embodiment is disposed under the backplate 6, unlike the temperature detection film layer 20 of the first embodiment which is disposed between the self-luminous display panel 10 and the backplate 6. In this case, the sensor elements of the temperature detection layer 20 are closer to the self-luminous display panel 10, which can reduce an influence of a sensor film on a display layer and also obtain a better adjustment effect, thus reducing a risk in a manufacturing process.

Specifically, the temperature detection film layer 20 is disposed between the backplate 6 and the foam layer 7.

### Third Embodiment

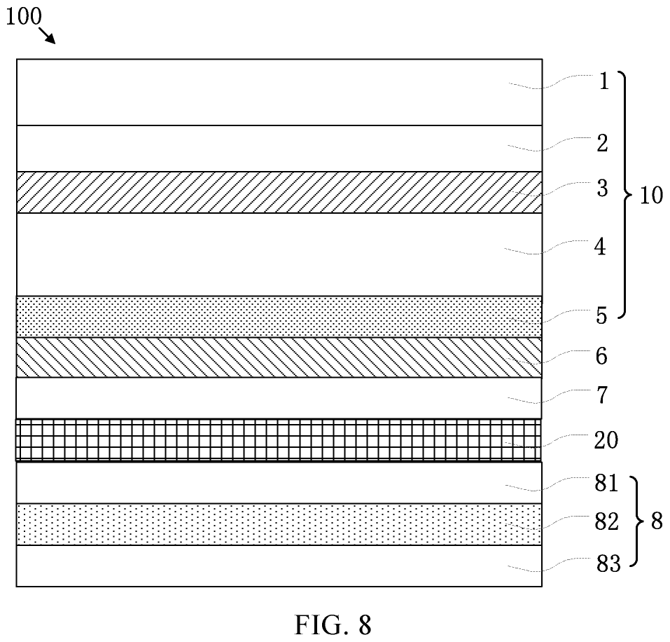

As shown in FIG. 8, the self-luminous display device 100 in the third embodiment comprises most technical features of the second embodiment. The third embodiment is different from the second embodiment in that, the temperature detection film layer 20 of the third embodiment is disposed under the foam layer 7, unlike the temperature detection film layer 20 of the second embodiment which is disposed between the backplate 6 and the foam layer 7.

Specifically, the temperature detection film layer 20 is disposed between the foam layer 7 and the heat dissipation functional layer 8.

### Fourth Embodiment

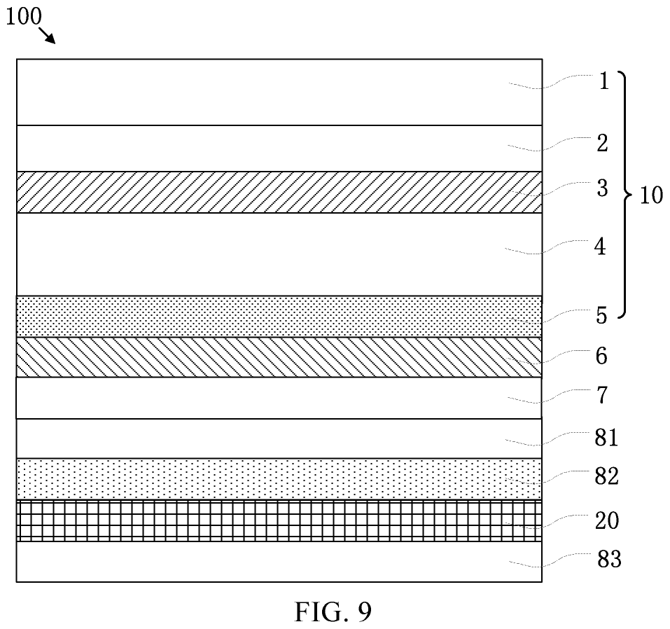

As shown in FIG. 9, the self-luminous display device 100 in the fourth embodiment comprises most technical features of the third embodiment. The fourth embodiment is different from the third embodiment in that, the temperature detection film layer 20 of the fourth embodiment is disposed in the heat dissipation functional layer 8, unlike the temperature detection film layer 20 of the third embodiment which is disposed between the foam layer 7 and the heat dissipation functional layer 8.

To be specific, the temperature detection film layer 20 is disposed between the graphite layer 82 and the copper foil layer 83.

### Fifth Embodiment

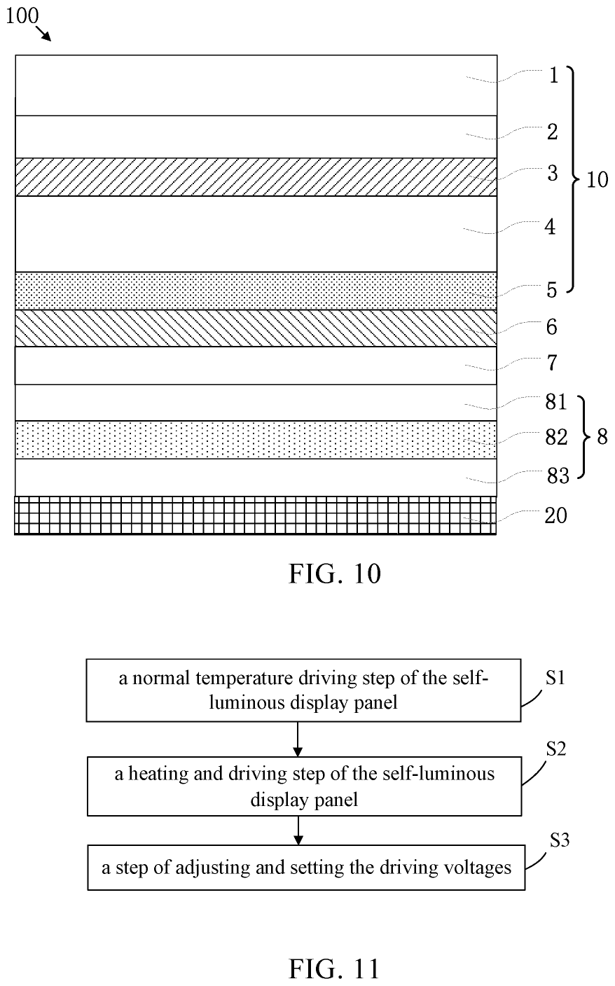

As shown in FIG. 10, the self-luminous display device 100 in the fifth embodiment comprises most technical features of the fourth embodiment. The fifth embodiment is different from the fourth embodiment in that, the temperature detection film layer 20 of the fifth embodiment is disposed under the heat dissipation functional layer 8, unlike the temperature detection film layer 20 of the fourth embodiment, which is disposed between the foam layer 7 and the heat dissipation functional layer 8.

To be specific, the temperature detection film layer 20 is disposed on a lower surface of the copper foil layer 83.

Based on a same inventive concept, as shown in FIG. 11, the present invention also provides a compensation voltage setting method of the self-luminous display device 100, comprising steps S1-S3:

S1: a normal temperature driving step of the self-luminous display panel 10 is performed to drive the pixel units 12 of the self-luminous display panel 10 at a room temperature, and detect and record brightness values and driving voltage values of the pixel units 12;

S2: a heating and driving step of the self-luminous display panel 10 is performed to gradually heat up the pixel units 12 of the self-luminous display panel 10, adjust the driving voltages to maintain the brightness of the pixel units 12 constant, and detect and record the real-time driving voltage values, varying with the temperatures, of the pixel units 12; and

S3: a step of adjusting and setting the driving voltages is performed, wherein the real-time driving voltage values, varying with the temperatures, of the pixel units 12 are input to the driving unit 11, and the driving unit 11 adjusts the driving voltages of the pixel units 12 in real time according to the temperature values of the self-luminous display panel 10 detected by the temperature detection film layer 20, so that the brightness of each of the pixel units 12 remains constant when the temperature changes. Specifically, the temperature sensors 22 in the temperature detection film layer 20 detect the temperature values of the display panel and transmits them to the sensing control unit 21, and the sensing control unit 21 is configured for storing information related to temperatures/grayscale voltages/data compensation voltages obtained in step S2 to provide the driving unit 11 with the data compensation voltage required by each of the pixel units 12 according to a position of the corresponding temperature sensor 22. The driving unit 11 outputs the driving voltages to the pixel units 12 according to voltage values of the data compensation voltages.

Advantages of the present invention are as follows. The present application provides a display device and a driving method thereof. The present application provides a temperature detection film layer which comprises a sensing control unit and temperature sensors and is arranged at one side of a self-luminous display panel. Accordingly, temperatures of the self-luminous display panel are detected by the temperature sensors and fed back to the sensing control unit. The sensing control unit provides a driving unit with a data compensation voltage required by each pixel unit according to a position of the corresponding temperature sensor, so that the driving unit can adjust a driving voltage of each pixel unit in real time to reinforce brightness of a darker area and lower brightness of a brighter area, thereby improving overall display uniformity.

The above are only the preferable embodiments of the present invention. It should be noted that improvements and modifications can be made by those of ordinary skill in the art without departing from the principle of the present invention, and such improvements and modifications should be deemed to be within the protection scope of the present invention.

1. A self-luminous display device, comprising:
a self-luminous display panel provided with a driving unit and a plurality of pixel units, wherein the pixel units are all electrically connected to the driving unit; and
a temperature detection film layer attached to one side of the self-luminous display panel for real-time detection of a plurality of temperature values of the self-luminous display panel;
wherein the temperature detection film layer is provided with a sensing control unit and a plurality of temperature sensors arranged in an array, all the temperature sensors are electrically connected to the sensing control unit, the sensing control unit is electrically connected the driving unit of the self-luminous display panel, and the driving unit is configured to adjust a driving voltage of each of the pixel units in real time according to the temperature values of the self-luminous display panel.

2. The self-luminous display device according to claim 1, wherein the sensing control unit is an integrated circuit chip, and the integrated circuit chip is disposed in the temperature detection film layer.

3. The self-luminous display device according to claim 2, wherein the temperature sensors are arranged around the integrated circuit chip.

4. The self-luminous display device according to claim 1, wherein the pixel units comprise a plurality of red sub-pixels, a plurality of green sub-pixels, and a plurality of blue sub-pixels.

5. The self-luminous display device according to claim 4, wherein each of the red sub-pixels is arranged corresponding to one of the temperature sensors, each of the green sub-pixels is arranged corresponding to one of the temperature sensors, and each of the blue sub-pixels is arranged corresponding to one of the temperature sensors.

6. The self-luminous display device according to claim 1, wherein each of the pixel units is arranged corresponding to one of the temperature sensors.

7. The self-luminous display device according to claim 1, wherein multiple ones of the pixel units are arranged corresponding to one of the temperature sensors.

8. The self-luminous display device according to claim 1, further comprising:
a backplate attached to a lower surface of the self-luminous display panel.

9. The self-luminous display device according to claim 8, wherein the temperature detection film layer is disposed between the self-luminous display panel and the backplate.

10. The self-luminous display device according to claim 8, wherein the temperature detection film layer is disposed under the backplate.

11. The self-luminous display device according to claim 8, further comprising:
a foam layer attached to a lower surface of the backplate.

12. The self-luminous display device according to claim 11, wherein the temperature detection film layer is disposed between the backplate and the foam layer.

13. The self-luminous display device according to claim 11, wherein the temperature detection film layer is disposed under the foam layer.

14. The self-luminous display device according to claim 11, further comprising:
a heat dissipation functional layer attached to a lower surface of the foam layer.

15. The self-luminous display device according to claim 14, wherein the temperature detection film layer is disposed between the foam layer and the heat dissipation functional layer.

16. The self-luminous display device according to claim 14, wherein the temperature detection film layer is disposed in the heat dissipation functional layer.

17. The self-luminous display device according to claim 14, wherein the temperature detection film layer is disposed under the heat dissipation functional layer.

18. The self-luminous display device according to claim 14, wherein the heat dissipation functional layer comprises:
a base layer attached to the lower surface of the foam layer;
a graphite layer disposed on a lower surface of the base layer; and
a copper foil layer attached to a lower surface of the graphite layer;
wherein when the temperature detection film layer is disposed in the heat dissipation functional layer, the temperature detection film layer is disposed between the graphite layer and the copper foil layer; and when the temperature detection film layer is disposed on a lower surface of the heat dissipation functional layer, the temperature detection film layer is disposed on a lower surface of the copper foil layer.

19. The self-luminous display device according to claim 1, wherein the sensing control unit is configured to store information related to temperatures/grayscale voltages/data compensation voltages to provide the driving unit with a data compensation voltage required by each of the pixel units according to a position of the corresponding temperature sensor.
